(19) United States
(12) Patent Application Publication
(10) Pub. No.: US 2007/0092809 A1
(43) Pub. Date: Apr. 26, 2007

(54) Fabrication of rear projection surface using reversal emulsion

(75) Inventors: Lee W. Tutt, Webster, NY (US); David Kessler, Rochester, NY (US); Junwon Lee, Webster, NY (US); Robert B. Bayley, Hilton, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 11/255,808

(22) Filed: Oct. 21, 2005

(51) Int. Cl. G03F 1/00; G03B 21/56

(52) U.S. Cl. 430/6; 359/460

(57) ABSTRACT

A method for fabrication of a rear projection article forms an arrangement of refractive elements on one surface of a transparent support and forms an apertured surface on the opposite surface of the support. A photographic positive reversal emulsion is applied to the opposite surface of the substrate to form a light-sensitive layer. Visible light is directed, as exposure radiation, through the refractive elements, exposing the light sensitive layer to form an exposed layer. The exposed layer is developed photographically using a positive reversal process to form the apertured surface thereby.

### FIELD OF THE INVENTION

This invention generally relates to rear projection surfaces and more particularly relates to a method for fabrication of a rear projection surface using reversal emulsion exposure and development techniques.

### BACKGROUND OF THE INVENTION

Rear projection screens were initially developed and manufactured as viewing surfaces for specialized displays that projected images from slides or film. With the advent of recent electronic imaging technologies for rear projection television and other display apparatus, there is renewed interest in rear projection surfaces. In the rear projection environment, with the audience and projector on opposite sides of the display surface, various design criteria are of importance. One problem of particular importance is image contrast, which would be compromised by reflection of stray light from the audience side of the display surface as well as by stray light from the projection side. In order to maximize image contrast and provide projected light at the desired angles, rear projection screens have been manufactured with a type of aperture mask, whereby the projected light is directed for display through an array of apertures, or aperture mask layer, formed in a light-absorptive black material. Referring to FIG. 1A, these apertures on a rear projection screen 10 can be in the form of “black stripe” linear apertures 12 or, alternately, may be formed as an array of discrete apertures 14 as shown in FIG. 1B, each aligned with corresponding lenslet or lenticular components, as is well known to those skilled in the imaging arts.

Simple methods for forming the aperture array include printing onto the display screen surface; however, alignment of apertures with refractive structures on the display screen itself is difficult to achieve by printing. The problem has become more complex as design of rear projection screens has become more elaborate, with arrays of cylindrical lenses or arrays of lenslets that must be aligned to the apertures. In response, various types of self-alignment techniques have been developed for “black matrix” or “black stripe” aperture alignment. For example:

U.S. Pat. No. 2,338,654 entitled “Projection Screen” to MacNeille describes forming a black stripe aperture array by exposing a photographic emulsion applied to the projection screen;

U.S. Pat. No. 2,618,198 entitled “Projection Screen” to Luboshez describes a rear projection screen having multiple layers and crossed lenticular lenses on the projection side and having aperture arrays formed using a photographic full reversal process;

U.S. Pat. No. 5,870,224 entitled “Lenticular Sheet, Rear-Projection Screen or TV Using the Same, and Fabrication Method for Said Lenticular Sheet” to Saitoh et al. describes a rear projection screen having a lenticular surface and a black stripe pattern formed by applying a toner to exposed areas of a UV sensitized resin;

U.S. Pat. No. 5,897,980 entitled “Method of Imparting Contrast Enhancement Properties to Diffusing, Depixelating or Projection Screens” to Phillips et al. describes exposure of a photopolymerisable monomer to form a black stripe matrix which can then be applied to the screen by a contact printing method;

PCT Patent Application No. WO 00/67071 entitled “Projection Screen” discloses forming a rear projection screen by irradiating a layer of photosensitive material through microlenses on the opposite surface.

Early rear projection displays, manufactured according to the '654 MacNeille patent and the '198 Luboshez patents cited above, were fabricated using the standard photographic development and exposure techniques of a full reversal process. In the full reversal process, there are two major stages. In the first stage, the following processing steps are performed:

i) an exposure step, in which the aperture pattern is exposed onto the photographic material, forming silver where exposure is applied;

ii) a first developer step;

iii) a rinse step;

iv) a bleach step;

v) a second rinse step; and,

vi) a clearing bath step.

At the conclusion of the first stage, the silver in the exposed areas has been removed. In the second stage of the full reversal process, the remaining silver halide material (unexposed in the first stage) is “printed up”, or oxidized. The following steps are performed:

i) a second developer step;

ii) a second rinse step;

iii) a fix step;

iv) another wash step;

v) a solution step; and,

vi) a drying step.

This full reversal process is described, for example, in U.S. Pat. No. 2,193,023 entitled “Photographic Reversal Process” to Evans et al. and in KODAK Technical Data, Publication No. J-87, entitled “KODAK PROFESSIONAL T-MAX 100 Direct Positive Film Developing Outfit”.

In general terms, the two stage full reversal process described above can be characterized as being fairly complex and somewhat subject to operator judgment and variability. Particularly for large sheets, the two-stage full reversal process can prove to be time-consuming and, due to the number of steps and number of different materials used, there is a likelihood of operator error. There are also concerns related to the number of chemical baths required to process full reversal media. Other disadvantages to the use of photographic emulsions have been noted such as low transparency of apertures and poor age performance with photographic emulsion techniques, particularly exacerbated by heat from the projected light.

With the recent upsurge of interest in rear projection screen fabrication, the same basic approach of “in situ” or self-alignment technique described in earlier patents, such as the '654 MacNeille patent and the '198 Luboshez patents cited above, has been adapted. The current arena, however, with spatial light modulators that provide electronically generated images, is more demanding. Thus, relative to the requirements these new imaging technologies impose, rear projection screens of earlier vintage typically exhibit, to at least some degree, inadequate performance and would not be particularly well suited to the requirements of more modem rear projection apparatus. Moreover, the actual two-stage procedure outlined above and required for manufacture of rear projection would be prohibitively difficult to implement in manufacturing a continuous web. In recent years UV-cured photosensitive emulsions have been utilized, for example, as is described in the '224 Saitoh et al. and '980 Phillips et al. patents, recent black matrix fabrication methods employ UV-curable polymers rather using than the photographic emulsion techniques proposed years earlier. UV-curing provides a generally more robust and forgiving method than did the earlier normal reversal process. Moreover, the use of UV-sensitive emulsions offers at least some opportunities for higher volume fabrication.

While UV curing methods have been widely adopted, however, there are a number of inherent drawbacks to aperture self-alignment for rear projection screens using these techniques. A key problem relates to the requirement that the material components of the screen itself be transparent to UV and that refractive elements on the screen, such as lenslet array or lenticular segments, be capable of suitably focusing the UV radiation. This requirement limits the range of materials that can be used for rear projection screen manufacture. Another related problem is that, even for materials capable for UV processing, refraction of the incident light at UV wavelengths is typically at different angles than for projected visible light. This complicates fabrication further, typically resulting in some compromise from optimal aperture dimensions and location, with consequent reduction in image quality. As yet another drawback of the conventional UV exposure approach, apertures lose some clear definition from the mask, due to imperfections inherent to toner adhesion. Further the densities achievable using toner are limited, particularly under conditions of high-power projection.

With the appearance of less expensive electronic color image-generation solutions for television and related backlighting applications, there is considerable interest in solutions that hold promise for high-volume, low-cost manufacture. Due to the shortcomings noted above, neither conventional full reversal photographic processes nor UV-based fabrication techniques offer attractive alternatives for high-volume, continuous web-based fabrication.

### SUMMARY OF THE INVENTION

The present invention provides a method for fabrication of a rear projection article comprising:

a) forming an arrangement of refractive elements on one surface of a transparent support; and

b) forming an apertured surface on the opposite surface of the support with the steps of:
i) applying a photographic positive reversal emulsion to the opposite surface of the substrate to form a light-sensitive layer;
ii) directing visible light, as exposure radiation, through the refractive elements, and exposing the light sensitive layer to form an exposed layer; and
iii) developing the exposed layer photographically using a positive reversal process to form the apertured surface thereby.

It further provides a system for fabrication of a rear projection article comprising:

a) an exposure apparatus for providing exposure light in the visible range toward a transparent support, wherein the transparent support comprises:
i) a coated side coated with a positive photographic emulsion;
ii) a refractive side for receiving the exposure light, the refractive side comprising a plurality of refractive elements, each refractive element directing incident light toward focus at a corresponding area of the coated side, forming an exposed support thereby;

b) a development apparatus comprising:
i) a developer tank for providing a bath of developer solution;
ii) a fixer tank for providing a bath of fixer solution;
iii) a wash apparatus for providing a washing liquid;

c) a transport apparatus for transporting the exposed support successively through the developer tank, the fixer tank, and the wash apparatus, forming optical apertures in the coated side and thereby forming an apertured surface.

It also provides a rear projection article comprising:

a) an incident light surface for facing toward a projector apparatus, the surface comprising a plurality of refractive elements;

b) an apertured surface comprising an optically opaque mask with an array of apertures, wherein, for each of at least a plurality of apertures, there is a corresponding, optically aligned refractive element on the incident light surface; wherein the optically opaque mask is formed from a developed photobleach emulsion or a developed core shell emulsion. Said rear projection display apparatus may also include a projector apparatus for providing an image-bearing light.

It is a feature of the present invention that it provides a method for fabricating a rear projection screen that uses high-contrast photographic exposure technology. It is an advantage of the present invention that it provides a method for inexpensive fabrication of high-contrast rear projection screens. It is a further advantage of the present invention that it uses visible light for aperture formation, allowing proper placement and size of apertures for rear projection applications. It is yet a further advantage of the present invention that it provides a method for low-cost, continuous web-based manufacture of a rear projection article. These and other objects, features, and advantages of the present invention will become apparent to those skilled in the art upon a reading of the following detailed description when taken in conjunction with the drawings wherein there is shown and described an illustrative embodiment of the invention. The present invention may be particularly useful with rear projection TVs, particularly those utilizing liquid crystal displays.

### BRIEF DESCRIPTION OF THE DRAWINGS

While the specification concludes with claims particularly pointing out and distinctly claiming the subject matter of the present invention, it is believed that the invention will be better understood from the following description when taken in conjunction with the accompanying drawings, wherein:

FIG. 1A is plan view showing apertures in a black stripe matrix arrangement;

FIG. 1B is a plan view showing an array of apertures in an alternate arrangement;

FIG. 2 is a cross-section view of a rear projection article formed according to the present invention;

FIG. 3 is a side view of an exposure apparatus for directing exposure light onto a sensitized medium for exposing a pattern of apertures corresponding to an arrangement of refractive structures;

FIG. 4 is a schematic side view of a fabrication apparatus for forming a rear projection article in web-based manufacture; and,

FIG. 5 is a block diagram of a rear projection apparatus using the rear projection article of the present invention.

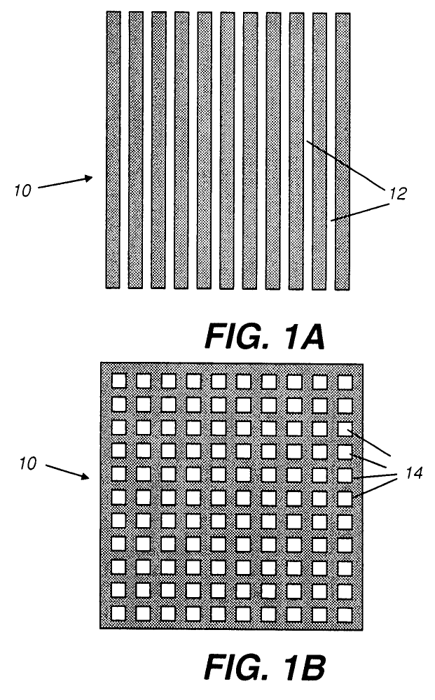

### DETAILED DESCRIPTION OF THE INVENTION

The present description is directed in particular to elements forming part of, or cooperating more directly with, apparatus in accordance with the invention. It is to be understood that elements not specifically shown or described may take various forms well known to those skilled in the art.

In contrast to the teaching of the Brady et al. '425 disclosure noted hereinabove, and distinct from conventional approaches currently in use for rear projection screen manufacture, the apparatus and method of the present invention adapt photographic reversal techniques and apparatus as advantageous solutions to the challenge of low-cost, high-volume rear projection fabrication. A single stage reversal emulsion process, also termed a “positive emulsion” process eliminates a number of processing steps and has been shown to be more robust than was the earlier full reversal process.

Unlike its full reversal predecessor, the more recent positive reversal process is relatively straightforward to implement, is low-cost, requires very little time, and can be readily adapted to continuous, web-based manufacture onto a lengthy segment of a flexible substrate material, which is typically fed from one roll, processed, and fed to another roll or otherwise processed upon completion. Characteristics of direct positive emulsion response and processing are well known and are given, for example, in The Theory of the Photographic Process, Fourth Edition, Macmillan Publishing Co., Inc., pp. 182-193.

There are two basic types of positive reversal emulsions:

a) photobleach emulsions. This type of fine-grained emulsion uses an electron-trapping dye and is prefogged in some manner. For example U.S. Pat. No. 3,598,596 entitled “Direct Positive Silver Halide Emulsions Containing Sensitizing Dye with a 1,2-Diaryl Substituted Indole Nucleus” to Chapman, incorporated herein by reference, discloses a dye that is particularly suitable for use with this type of positive reversal photographic emulsion. The dyes described in U.S. Pat. No. 3,598,596 are generally cyanine dyes comprising first and second 5- to 6-membered nitrogen containing heterocyclic nuclei joined by methine linkage; the first of said nuclei being a 1,2-diarylindole nucleus joined at the 3-carbon atom to said linkage; and said second nucleus being selected from the group consisting of a 1,2-diarylindole nucleus joined at the 3-carbon atom to said linkage, and a desensitizing nucleus joined at a carbon atom thereof to said linage to complete said cyanine dye and

b) core shell emulsions. This type of emulsion uses a larger grain and is similar to photosensitive emulsions used with some types of microfilm and so-called “instant” film. For example, U.S. Pat. No. 5,532,119 entitled “High-speed Direct-positive Photographic Elements Utilizing Core-shell Emulsions” to Arcus et al., incorporated herein by reference, describes the use of core shell emulsions as a type of direct-positive emulsion.

Because of its slower speed, simpler formulation, and use of standard black-and-white developer, the photobleach emulsion type of positive reversal emulsion is generally advantaged over the core shell emulsion type for most embodiments of the present invention; however, either type of positive reversal emulsion could be used.

A conventional approach to forming direct-positive images is to use photographic elements employing internal latent image-formling silver halide grains. After imagewise exposure, the silver halide grains are developed with a surface developer—that is, one which will leave the latent image sites within the silver halide grains substantially unrevealed. Simultaneously, either by uniform light exposure or by the use of a nucleating agent, the silver halide grains are subjected to development conditions that would cause fogging of a negative-working photographic element. The internal latent image-forming silver halide grains that receive actinic radiation during imagewise exposure develop under these conditions at a slow rate as compared to the internal latent image-forming silver halide grains not imagewise exposed. The result is a direct-positive silver image.

Fabrication and Processing Sequence

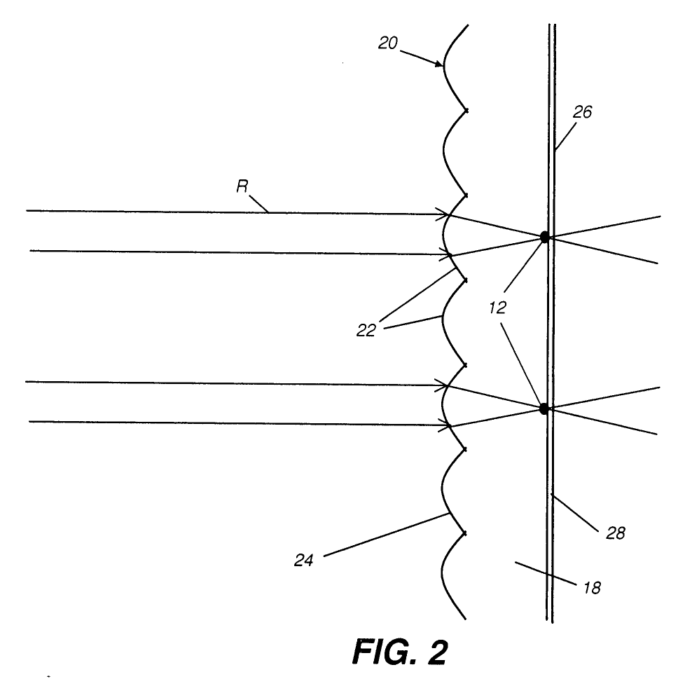

Referring to FIG. 2, there is shown, in cross-section and greatly magnified and exaggerated, a small portion of a rear projection article 20, such as a rear projection screen, formed on a transparent support or substrate 18 such as an inorganic oxide eg. glass, or a plastic support eg. polyethylene terephthalate, polycarbonate, or cellulose triacetate. The support must be transparent, compatible with the developing and coating solutions and have an optical microstructure or allow a microstructure be attached before exposure. Refractive elements 22 such as a lenslet array or lenticular array, for example, are formed on a featured surface 24 of rear projection article 20, facing a projection light source (not shown in FIG. 2). Two rays R of light from the projection light source are traced in dotted lines in FIG. 2. Refractive element 22 focuses the substantially collimated light rays R toward each aperture 12 on an apertured surface 26 of rear projection article 20. An optional finish coat 28 can be applied to apertured surface 26. Finish coat 28 can be any of a number of materials, including materials that provide a protective treatment for apertured surface 26.

As was described in the background section above, each aperture 12 is aligned to a corresponding refractive element 22 using light. Using the method of the present invention, visible light rays R can be used to form apertures 12. This is accomplished by coating a positive emulsion layer onto apertured surface 26, exposing the emulsion layer, and developing the exposed portions to provide apertures 12 on an aperture mask layer.

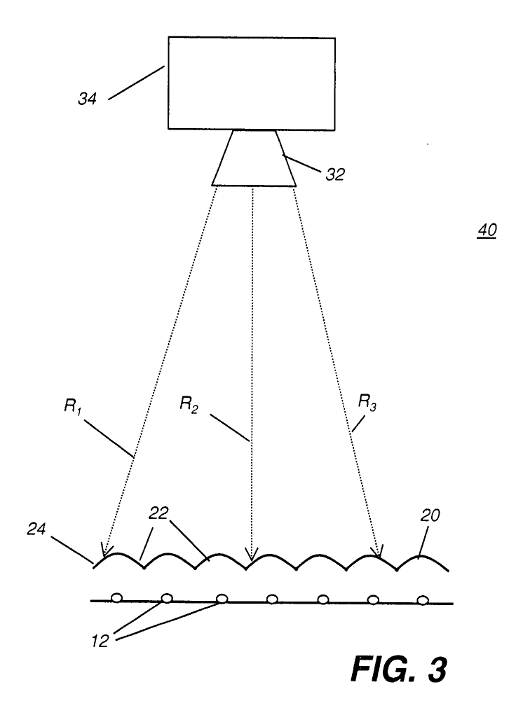

Referring to FIG. 3 there is shown a side view of an exposure apparatus 40 for directing exposure light onto the sensitized, unexposed rear projection article 20 for exposing a pattern of apertures 12 corresponding to the arrangement of refractive elements 22. A light source 32 provides actinic exposure radiation that is refracted by refractive elements 22 to form apertures 12. Advantageously, light source 32 is part of a projector apparatus 34, preferably having a projection lens, and projector apparatus 34 closely emulates the actual projection device with which this section of rear projection article 20 is used in a rear projection apparatus. As is shown in FIG. 3, some rays R2 are normal to featured surface 24. Other rays, such as rays R1 and R3 shown at the extreme edges of the projected light beam, are at some angle from normal. Using in-situ aperture 12 formation is advantageous with this arrangement, since it allows each aperture 12 to be aligned at the best location for its corresponding refractive element 22, handling projection light at its appropriate angle.

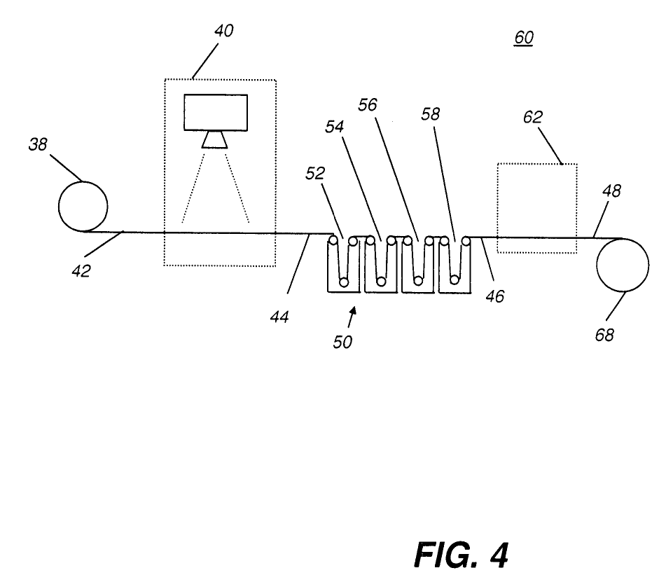

Referring to FIG. 4, there is shown a fabrication apparatus 60 for forming a rear projection screen or other type of flexible rear projection article 20 according to the present invention. Sensitized, unexposed media 42, coated with a suitable positive emulsion such as a photobleach or core shell emulsion as noted above, is provided from a roll 38 or other source. Exposure apparatus 40 directs actinic radiation to expose the coated unexposed media 42, forming an exposed media 44. A developer apparatus 50 then provides the chemical processing needed in order to develop. Developer apparatus successively guides exposed media 44 through a developer tank 52, followed by an optional rinse tank 54. Next, exposed media 44 is routed through a fixer tank 56. Lastly, a wash tank 58 or other apparatus is used to clear residual chemicals, forming a developed media 46. An optional finishing apparatus 62 applies a finish coat 28, as was shown in FIG. 2, for example. Other finishing operations performed at finishing apparatus 62 might include drying, heat application, or other suitable finishing operations. A finished article 48 can then be cut to suitable sizes for providing rear projection article 20 (FIG. 2) or can be stored on a roll 68 or in some other form. As is shown in FIG. 4, fabrication apparatus 40 advantageously provides a relatively flat path for media transport and can be designed without a requirement for highly serpentine film loops and routing.

Fabrication apparatus 60 as shown in FIG. 4 provides a conventional black-and-white photographic processing sequence for exposure and development of a high-contrast image using a positive emulsion: developer, rinse, fixer, wash. Conventional black-and-white developer such as, for example, KODAK DK-50 Black & White Film Developer may be used. Other developers are described in U.S. Pat. No. 5,532,119 and 3,598,596 discussed above. This type of processing is straightforward and robust when contrasted with the full reversal process described in the background section given above. It requires less critical timing and fewer chemicals and poses fewer chemical hazards for processing or for disposition of waste. Standard black-and-white processing is silver-efficient and low-cost, each processing step requiring relatively little time. For example, exposed media 44 can be routed through its successive developer, rinse, fixer, and wash tanks 52, 54, 56, and 58 to emerge as developed media 46 in about one minute, using high temperature processing. Developer apparatus 50 can be assembled from standard film processing components and apparatus. In one embodiment, a conventional large-scale film processor, similar to a graphic arts processor, is employed for developer apparatus 50. Standard sets of photochemicals can be used, such as Kodak Rapid Access processing chemistry, for example.

Because it uses a simple set of processing steps, fabrication apparatus 60 allows in-line processing. This process can be adapted for use with commercial large-sheet film equipment and is particularly well suited for use with large sheets of sensitized media, producing a rear projection article having a dense opaque layer with apertures formed using visible light. In an alternate embodiment, still other functions could be performed, such as coating to form unexposed media 42. Refractive elements 22 could be formed into substrate 18 (FIG. 2) as part of an inline process that forms a coated unexposed media 42, exposes it, processes it, and finishes it, so that a single fabrication apparatus 60 performs the full set of fabrication tasks necessary for fabrication of a rear projection article.

The conventional full reversal process that had been disclosed for fabrication of early rear projection screens in the '654 MacNeille and '198 Luboshez patents would prove to be too cumbersome, requiring an excessive number of steps for any type of in-line processing using a system such as fabrication apparatus 60 shown in FIG. 4. Moreover, cost, complexity, speed, waste, timing, and inherent variability, as noted in the Brady et al. '425 disclosure, would render the conventional full reversal photographic process as impractical for rear projection article fabrication. While solutions to the problem that use UV or other types of non-visible radiation have been designed, these solutions place constraints on selection of substrate materials and require some compromise from ideal alignment of apertures 12.

Compared with its full reversal counterpart, the positive reversal emulsion process is less expensive and produces good contrast, with highly opaque densities. The positive reversal emulsion process is also resistant to fading, even under conditions of heat build-up. Thus, the positive reversal emulsion process overcomes many of the problems encountered with the earlier two-stage full reversal process. Most importantly, the reversal emulsion process uses visible light, allowing apertures to be formed from light emitted from the same optical components that are used for projection of the image. That is, aperture-forming light energy follows the same path as does image-forming light. Thus, apertures 12 can be formed in the precise location where projected light is needed, rather than in some approximate location resulting from the use of UV or other non-visible light exposure.

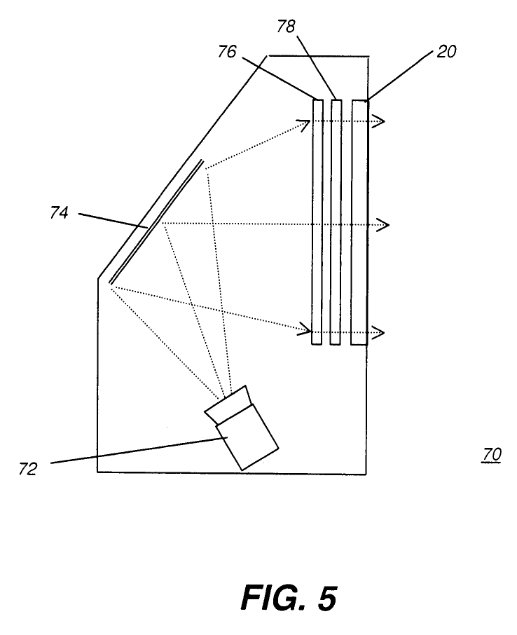

Referring to FIG. 5, there is shown a block diagram of a rear projection apparatus 70 using rear projection article 20 fabricated according to the present invention. A projector 72 directs image-bearing light, typically through a folding mirror 74, toward rear projection article 20 for display. The image-bearing light can be conditioned by supporting optical components such as a Fresnel lens sheet 76 and lenticular lens sheet 78. In the embodiment of FIG. 5, Fresnel lens sheet 76 provides some measure of collimation for the projected light. Other supporting optical articles that may be used include diffusers or polarizers, for example.

The invention has been described in detail with particular reference to certain preferred embodiments thereof, but it will be understood that variations and modifications can be effected within the scope of the invention as described above, and as noted in the appended claims, by a person of ordinary skill in the art without departing from the scope of the invention. For example, core shell direct positive emulsions could be used in place of photobleach emulsions. Light sources 32 could be matched to specific sections of rear projection article 20 or other rear projection article. Light source 32 could even be used to expose an arrangement of apertures 12 that is custom-designed for the characteristics of the light. Refractive elements 22 are typically lenses, a lenslet array, or some other arrangement of optical elements and may be formed onto one surface of a transparent support in any of a number of ways, including molding, scribing, lamination, or printing, for example.

Thus, what is provided is an apparatus and method for fabrication of a rear projection surface using reversal emulsion exposure and development techniques.

### PARTS LIST

10. Rear projection screen
12, 14. Aperture
18. Substrate
20. Rear projection article
22. Refractive element
24. Featured surface
26. Apertured surface
28. Finish coat
32. Light source
34. Projector apparatus
38. Roll
40. Exposure apparatus
42. Unexposed media
44. Exposed media
46. Developed media
48. Finished article
50. Developer apparatus
52. Developer tank
54. Rinse tank
56. Fixer tank
58. Wash tank
60. Fabrication apparatus
62. Finishing apparatus
68. Roll
70. Rear projection apparatus
72. Projector
74. Mirror
76, 78. Lens sheet

1. A method for fabrication of a rear projection article comprising:
a) forming an arrangement of refractive elements on one surface of a transparent support; and
b) forming an apertured surface on the opposite surface of the transparent support with the steps of:
i) applying a photographic positive reversal emulsion to the opposite surface of the substrate to form a light-sensitive layer;
ii) directing visible light, as exposure radiation, through the refractive elements, and exposing the light sensitive layer to form an exposed layer; and
iii) developing the exposed layer photographically using a positive reversal process to form the apertured surface .

2. A method according to claim 1 wherein the step of forming an arrangement of refractive elements comprises the step of forming a lenticular lens array.

3. A method according to claim 1 wherein the step of forming an arrangement of refractive elements comprises the step of forming a lenslet array.

4. A method according to claim 1 wherein the step of directing visible light comprises the step of directing visible light through a projection lens.

5. A method according to claim 1 wherein the step of applying a photographic positive reversal emulsion comprises the step of applying a photobleach emulsion.

6. A method according to claim 1 wherein the step of applying a photographic positive reversal emulsion comprises the step of applying a core shell direct positive emulsion.

7. A method according to claim 1 wherein the transparent support is provided on a continuous web.

8. A method according to claim 1 wherein the step of developing the exposed layer comprises the steps of:
i) developing the exposed layer;
ii) fixing the exposed layer; and
iii) washing said opposite surface to remove spent chemicals.

9. A system for fabrication of a rear projection article comprising:
a) an exposure apparatus for providing exposure light in the visible range toward a transparent support, wherein the transparent support comprises:
i) a coated side coated with a positive photographic emulsion;
ii) a refractive side for receiving the exposure light, the refractive side comprising a plurality of refractive elements, each refractive element directing incident light toward focus at a corresponding area of the coated side, forming an exposed support thereby;
b) a development apparatus comprising:
i) a developer tank for providing a bath of developer solution;
ii) a fixer tank for providing a bath of fixer solution;
iii) a wash apparatus for providing a washing liquid;
c) a transport apparatus for transporting the exposed support successively through the developer tank, the fixer tank, and the wash apparatus, forming optical apertures in the coated side and thereby forming an apertured surface.

10. The system of claim 9 wherein the development apparatus further comprises a rinse tank.

11. The system of claim 9 further comprising a finishing apparatus for providing a protective treatment to the apertured surface of the rear projection article.

12. The system of claim 9 wherein the refractive features are provided by a lenslet array.

13. The system of claim 9 wherein the refractive features are provided by a lenticular array.

14. A rear projection article comprising:
a) an incident light surface for facing toward a projector apparatus, the surface comprising a plurality of refractive elements;
b) an apertured surface comprising an optically opaque mask with an array of apertures, wherein, for each of at least a plurality of apertures, there is a corresponding, optically aligned refractive element on the incident light surface;
wherein the optically opaque mask is formed from a developed photobleach emulsion.

15. A rear projection article comprising:
a) an incident light surface for facing toward a projector apparatus, the surface comprising a plurality of refractive elements;
b) an apertured surface comprising an optically opaque mask with an array of apertures, wherein, for each of at least a plurality of apertures, there is a corresponding, optically aligned refractive element on the incident light surface;
wherein the optically opaque mask is formed from a developed core shell emulsion.

16. A rear projection display apparatus comprising:
a) a projector apparatus for providing an image-bearing light;
b) a rear projection article comprising:
i) an incident light surface for facing toward the image bearing light from the projector apparatus, the surface comprising a plurality of refractive elements;
ii) an apertured surface comprising an optically opaque mask with an array of apertures, wherein, for each of at least a plurality of apertures, there is a corresponding, optically aligned refractive element on the incident light surface;
wherein the optically opaque mask is formed from a developed photobleach emulsion.

17. The rear projection display of claim 16 further comprising a lens sheet for conditioning the image-bearing light.

18. The rear projection display of claim 16 further comprising a diffuser.

19. A rear projection display apparatus comprising:
a) a projector apparatus for providing an image-bearing light;
b) a rear projection article comprising:
i) an incident light surface for facing toward the image bearing light from the projector apparatus, the surface comprising a plurality of refractive elements;
ii) an apertured surface comprising an optically opaque mask with an array of apertures, wherein, for each of at least a plurality of apertures, there is a corresponding, optically aligned refractive element on the incident light surface;
wherein the optically opaque mask is formed from a developed core shell emulsion.

20. The rear projection display of claim 19 further comprising a lens sheet for conditioning the image-bearing light.

21. The rear projection display of claim 19 further comprising a diffuser.
